(19) United States
(12) Patent Application Publication
(10) Pub. No.: US 2002/0187615 A1
(43) Pub. Date: Dec. 12, 2002

(54) Method for forming isolations in memory devices with common source lines

(75) Inventor: Jih-Wei Liou, Hsin-Chu (TW)

Correspondence Address: LOWE HAUPTMAN GILMAN & BERNER, LLP, Suite 310, 1700 Diagonal Road, Alexandria, VA, 22314, US

(73) Assignee: UNITED MICROELECTRONICS CORP.

(21) Appl. No.: 09/875,152

(22) Filed: Jun. 7, 2001

(51) Int. Cl. H01L 21/76

(52) U.S. Cl. 438/424; 438/433

(57) ABSTRACT

In accordance with the present invention, a method for forming isolations in memory devices is disclosed. The key aspect of the present invention is the application of shallower isolations in the common source line only with enhanced deeper depth isolations in other areas. The present invention introduces an additional common source diffusion (CSD) mask which covers the common source line to resist the STI etching to construct a super shallow oxide layer only along the common source line. A two-stage STI etching process is utilized in accordance with the present invention. The first stage is a very shallow and edge-tapered etch, and the second stage is a vertical STI etch to a deeper depth required for flash and other devices in the same chip.

### BACKGROUND OF THE INVENTION

1. Field of the Invention

The present invention generally relates to a method for forming isolations in memory devices, and more particularly to a method for forming shallow trench isolation (STI) in memory devices to improve the electrical continuity of self-aligned common source line.

2. Description of the Prior Art

Semiconductor devices typically include multiple individual components formed on or within a substrate. The way to prevent unwanted components or structures from cross talk or shorting becomes significantly important, since the integration circuit density is continuously increased. Therefore, isolation techniques are very critical for the purpose of electrically insulating various portions or structures of the semiconductor device from other portions of the device. Traditional flash memory adopts the local oxidation (LOCOS) isolation technique, due to its wave shape bottom, which is easily implemented with the self-aligned source (SAS) module to reduce the cell gate distance. However, scale down LOCOS techniques reduce the effective spacing separating adjacent active regions in a semiconductor device and, thereby increases the reliability problem.

A conventional alternative design to avoid the disadvantages of the LOCOS technique comprises shallow trench isolation (STI). The main features of the STI technology are the elimination of the lateral field oxide (bird's beak), the use of a deposited oxide instead of a thermal oxide, and an excellent oxide planarization over the entire semiconductor wafer surface. This results in a high scalability of the STI process and makes it suitable, for example, for use in high density flash memory devices. For sub-micron ultra-large scaled integrated (ULSI) technology, the STI technique is indispensable to scale down the feature size of all devices. Though the sharp STI sidewall improves the isolation concern for most integrated circuit devices, also including a flash memory cell, however, the deep depth and rectangular shape of STI will enhance the discontinuity of common source resistant if the SAS module is utilized.

FIG. 1 illustrates a top view of a portion of a semiconductor substrate under fabrication as a flash memory device. Several unit cells 12,14 with source 16 and drain 18 formed by a control gate layer 20 deposited on top of an interpoly dielectric layer such as oxide-nitride-oxide (ONO) sandwich (not shown), and a floating gate layer 22. The source region 16 between the cell gates of cells 12 and 14 is shared, and contact 30 is formed in the drain region 18. Field oxide regions 24a, 24b formed by a STI process separate and isolate adjacent memory devices along a word line 20 (control gate layer). In forming flash memory devices, the source region 16 of the memory cells can be connected by a common source line 26. The use of such a common source line 26 saves die size by allowing designers to have many transistors share a common connection. The resistance of the common source line determines the size and overall performance of the device. Typically, the common source line is formed in a SAS process. In this process, the field oxide 24b separating the source regions of a number of cells are removed and implant made into the substrate with an impurity of the same type as formed the source regions to couple the source regions together to form the common source line.

FIG. 2 illustrating a cross-sectional view taken along a cutting line 2-2 in FIG. 1, a common source line 26 after the implantation process is shown. The electrical continuity of the self-aligned source with STI process, and more in general with completely recessed isolations 24b of the substrate, is a problem due to different impurity doping level along the common source line 26 between active areas (high zones) 16 and isolation areas (low zones) 24c. For the purpose of isolating adjacent devices, the STI is formed with a deep depth. At areas 28, these sections of the common source line 26 are pinched, having shallower junction depths than other implanted areas of the common source line 26 due to the great aspect ratio of recessed STI 24c. These areas 28 consequently have high resistance and therefore deleteriously affect the performance of devices.

It is well known that isolation regions or structures for semiconductor device vary in size depending on parameters or requirements necessary for proper electric isolation or charge carrier isolation. In some prior art techniques, a dual field isolation structure has been proposed. For example, in memory devices such as a flash memory device, larger isolation structures are applied to peripheral areas (non-core areas for input/output circuitry) of the devices where larger voltages are present. In contrast, smaller isolation structures are utilized in core areas such as memory array, where memory cells are packed closely together and operate at lower voltage levels. However, the dual isolation technique, which has deeper depth of isolations in peripheral regions and shallower isolations in core regions, still causes a reliability problem. If the isolation depth is reduced in the cell array, the bit line to bit line isolation will fail when high voltage operation applied, such as applying 5V to the drain region.

In view of the prior art described, it is a desire to provide a method which is able to guarantee the electrical continuity along the common source line of the memory array using the STI process, and also provide a great bit line to bit line isolation.

### SUMMARY OF THE INVENTION

The present invention is directed toward a method for forming isolations in memory devices with common source lines. The key aspect of the present invention is the application of shallower isolations in the common source line only and enhanced deeper depth isolations in other areas. The present invention introduces an additional common source diffusion (CSD) mask which covers the common source line to resist the STI etching to construct a super shallow oxide layer only along the common source line. The main advantage of using the CSD mask technique is that the self-aligned source module can be implemented with the STI technique to meet the requirement for minimization of the feature size. The resistance of a common source line can also be easily controlled to an acceptable level to meet the requirement for densification of flash memory cells. The second advantage is that the common source line width (gate to gate distance) can be scaled down to the minimum feature size of the process technique due to the enhanced continuity of the common source line, and this helps to reduce the cell size. The third advantage is that there is no sacrifice of the isolation between each bit line because the bit line isolation is still kept with a deeper depth of STI.

It is another object of this invention that a method for forming shallow trench isolations in flash memory array to construct a low resistance common source line without sacrificing the isolation requirement between each bit line.

It is a further object of this invention that a method for providing a two-stage STI etching process. The first stage is a very shallow and edge-tapered etch, and the second stage is a vertical STI etch to a deeper depth required for flash and other devices in the same chip.

In accordance with the present invention, in one embodiment, a method for forming isolations in memory devices is disclosed. The method comprises the step of providing a semiconductor substrate, such as a silicon substrate, having a common source region and a first region. The first region can be any region either in the core area or in the peripheral area. Then, a first opening with a first depth is formed in the common source region in the semiconductor substrate. Next, a second opening with a second depth in the first region is formed in the semiconductor substrate, wherein the second depth is greater than the first depth. Then, the first opening and the second opening are filled with a dielectric material to form a first isolation in the common source region and a second isolation in the first region in the semiconductor substrate. The step of forming the first opening comprises sequentially forming a pad oxide layer, a silicon nitride layer, and a cap oxide layer on the semiconductor substrate. Then, a first patterned photoresist on is formed on the cap oxide layer, wherein the first patterned photoresist defines the first opening in the common source region. The cap oxide layer, the silicon nitride layer, the pad oxide layer, and a portion of said semiconductor substrate are sequentially etched to form the first opening with a first depth in the common source region in the semiconductor substrate by using the first patterned photoresist as a mask. Next, the first patterned photoresist is removed. The step of forming the second opening with the second depth comprises forming a second patterned photoresist on the cap oxide layer, wherein the second patterned photoresist defines the second opening in the first region. Using the second photoresist as a mask, a second etch step is performed till the second depth is reached to form the second opening in the first region in the semiconductor substrate, wherein the second depth is greater than the first depth. Then, the second patterned photoresist is removed. The step for forming the first isolation and the second isolation comprises forming a liner oxide layer in the first opening and the second opening. Then, a silicon oxide layer is formed on the cap oxide layer and filling the first opening and the second opening. A chemical mechanical polishing process is applied to planarize the silicon oxide layer to expose the silicon nitride layer. Then, the silicon nitride layer and the pad oxide layer are removed. The method further comprises the step of forming a gate structure, a source/drain region, and a common source line to form a flash memory device.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a top view of a portion of a memory array in the prior art technique before the common source line is formed;

FIG. 2 is a schematic cross-sectional view taken along cutting line 2-2 in FIG. 1 which shows the discontinuity of the common source line when the common source line is formed;

FIG. 3 is a top view of a portion of a memory array in accordance with the present invention before a common source line is formed;

FIGS. 4A to 4D is a schematic cross-sectional view taking along a cutting line 4-4 in FIG. 3 during the process of forming STI regions in accordance with the present invention;

FIGS. 5A to 5D is a schematic cross-sectional view taking along a cutting line 5-5 in FIG. 3 during the process of forming STI regions in accordance with the present invention;

FIG. 6 is a schematic cross-sectional view taking along a cutting line 6-6 in FIG. 3 when STI regions is formed in accordance with the present invention; and

FIG. 7 is a schematic cross-sectional view after the STI regions in the common source region is etched to form the common source line in accordance with the present invention.

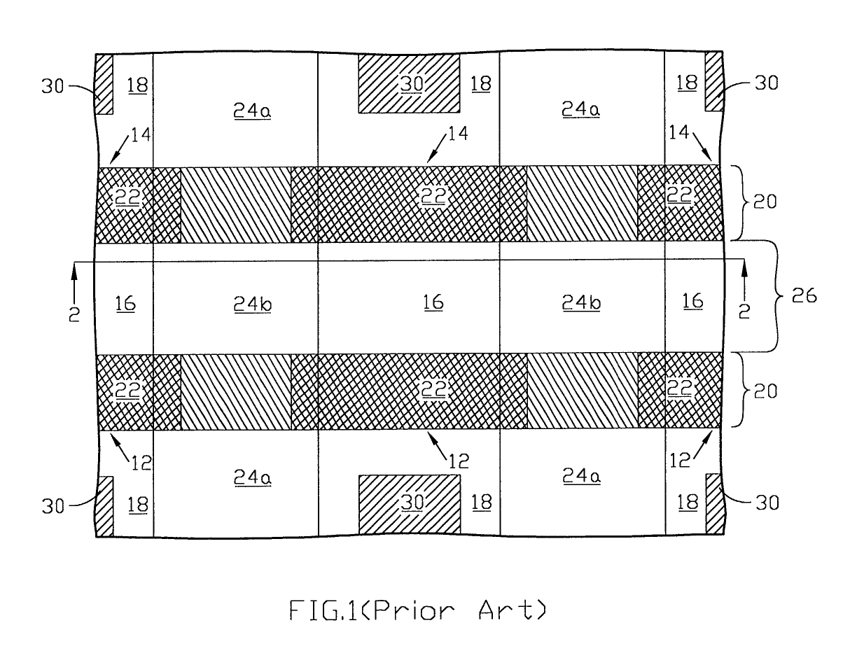

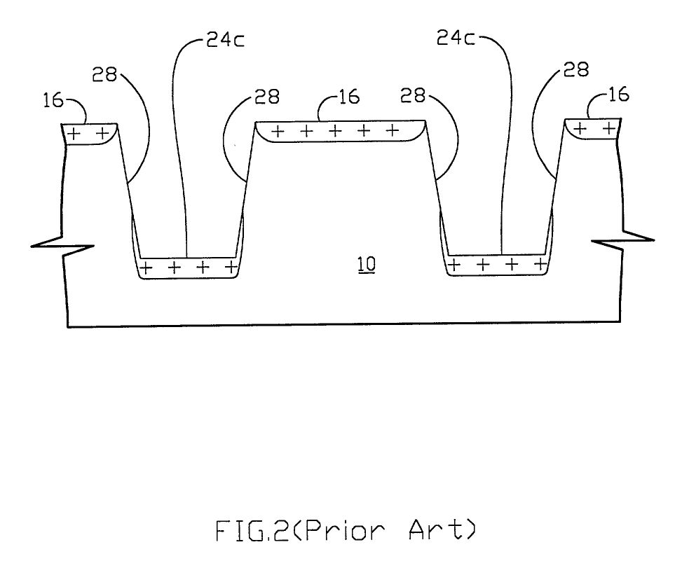

### DESCRIPTION OF THE PREFERRED EMBODIMENT

Some sample embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

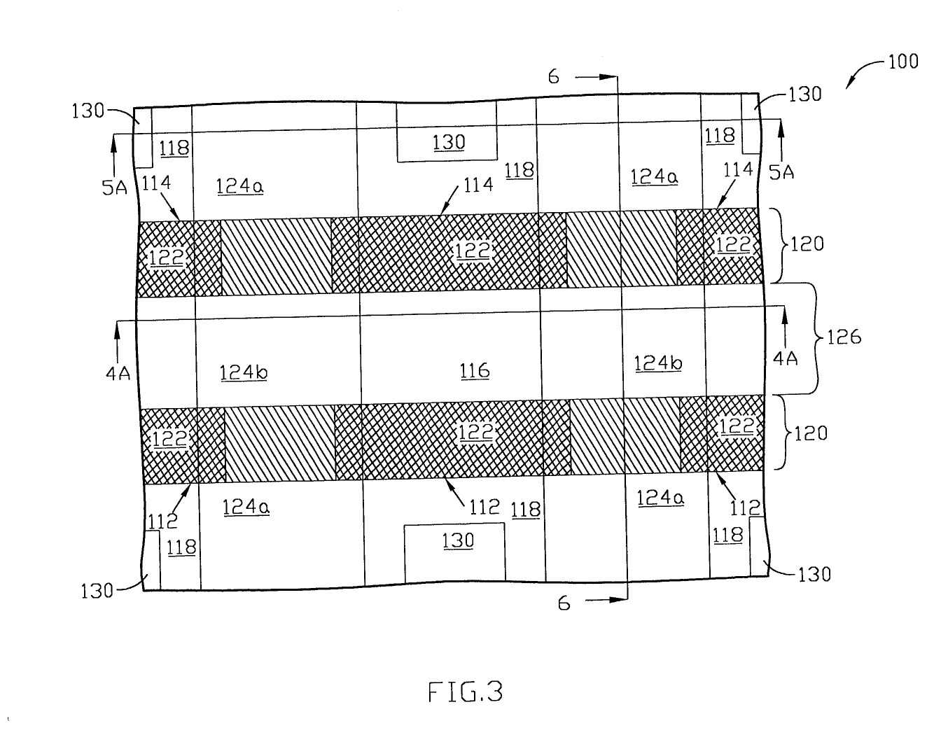

In one embodiment, a method for forming isolations in memory device with a common source line is provided. Typically, the common source line is formed in a self-aligned source process. In this process, the field oxide separating the source regions of a number of cells are removed and implant made into the substrate with an impurity of the same type as formed the source regions to couple the source regions together to form the common source line. The present invention introduces an additional common source diffusion (CSD) mask which covers the common source line to resist the STI etching to construct a super shallow oxide layer only along the common source line. A two-stage STI etching process is utilized in accordance with the present invention. The first stage is a very shallow and edge-tapered etch, and the second stage is a vertical STI etch to a deeper depth required for flash and other devices in the same chip. Referring to FIG. 3, a top view is shwon of a portion of a memory array in accordance with the present invention before a common source line is formed, that depicts a portion of a flash memory device 100 layout with memory cells 112, 114. The major layers such as field oxide 124a, 124b, active diffusion 118, common source diffusion 126 (common source region), poly-1 122 (floating gate), cell gate 120 (word line), self-aligned source (SAS) 116, and contacts 130 are shown. The field oxide 124b is later removed in the process when forming the common source line 126.

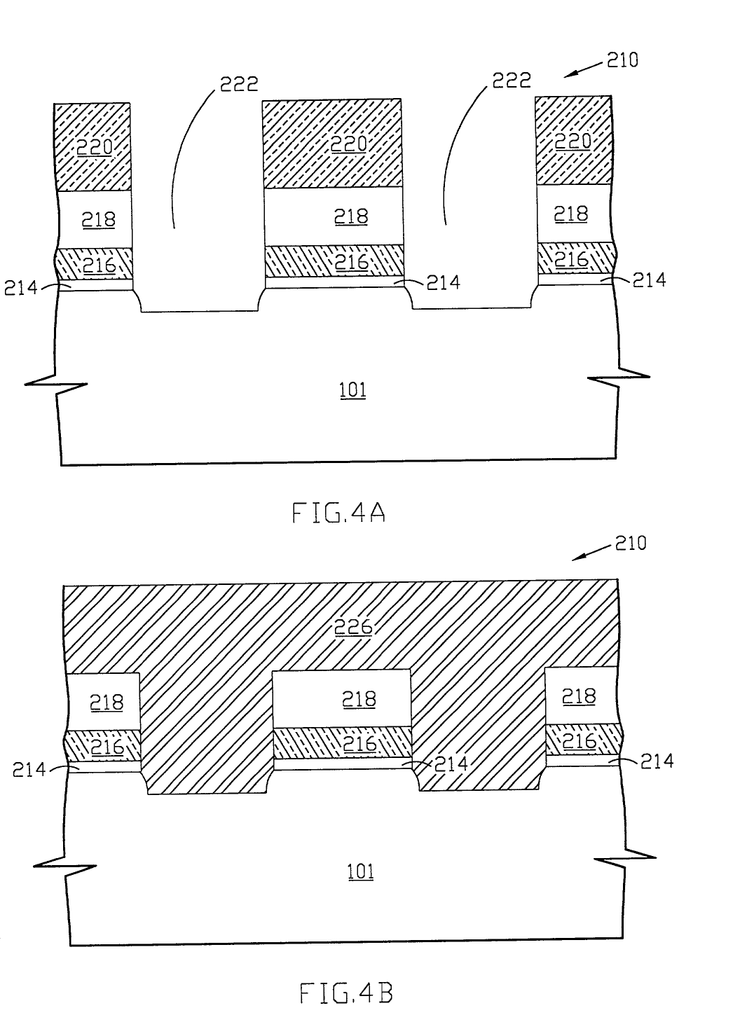

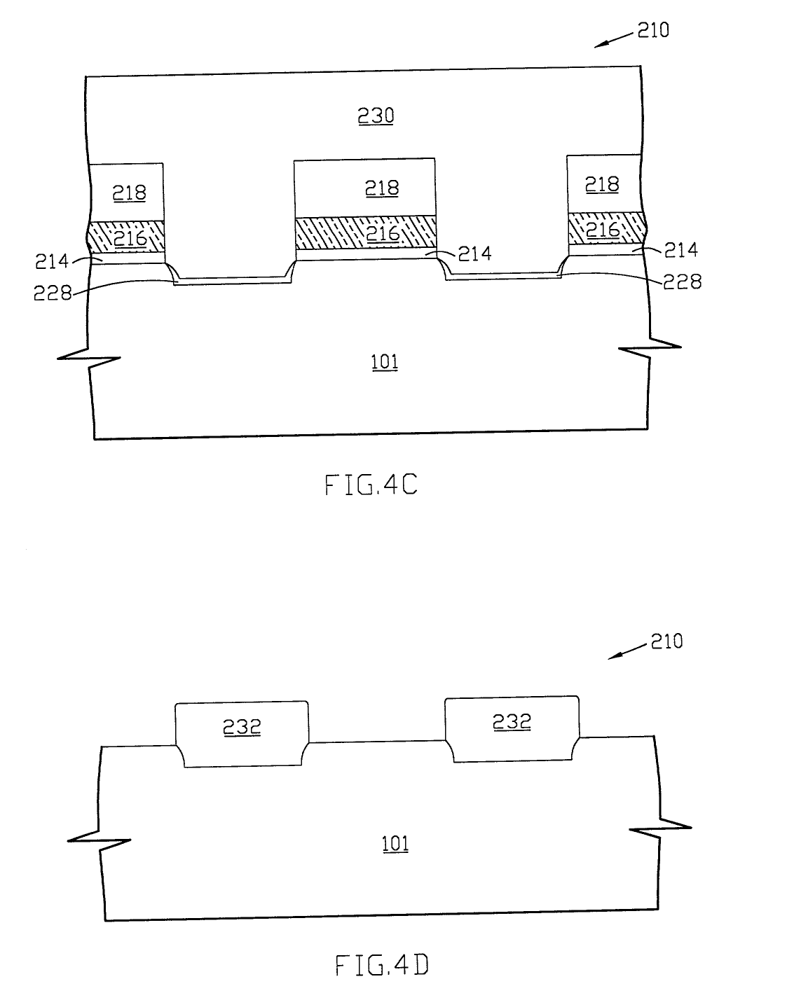

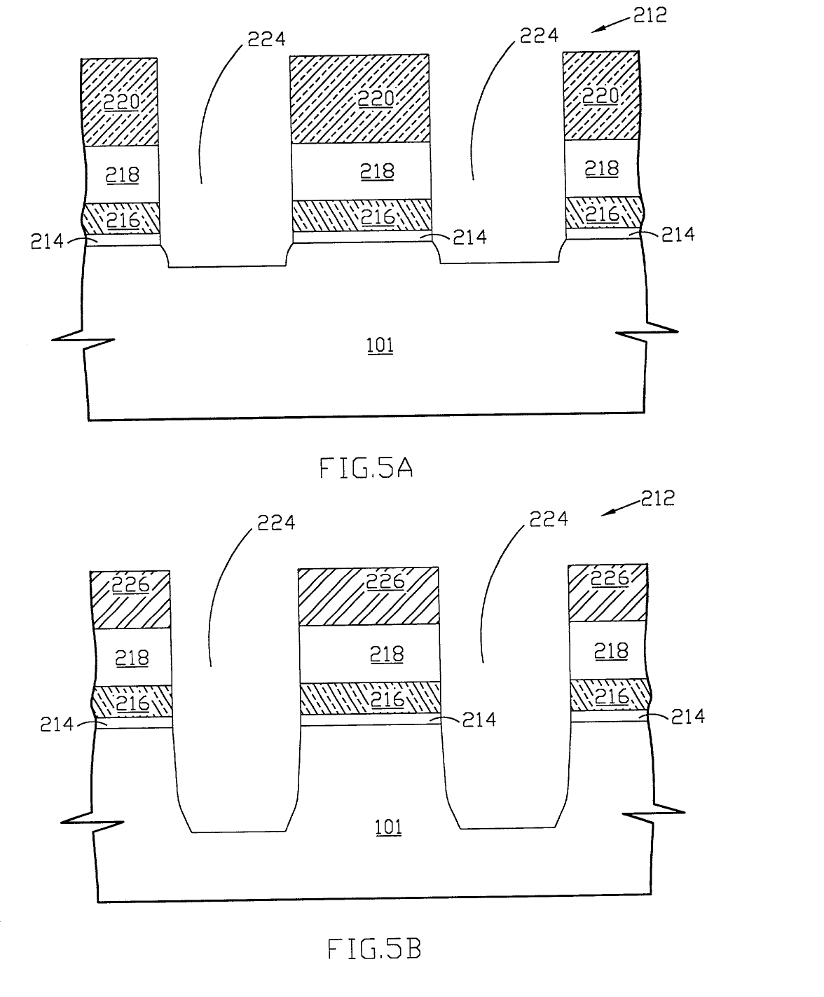

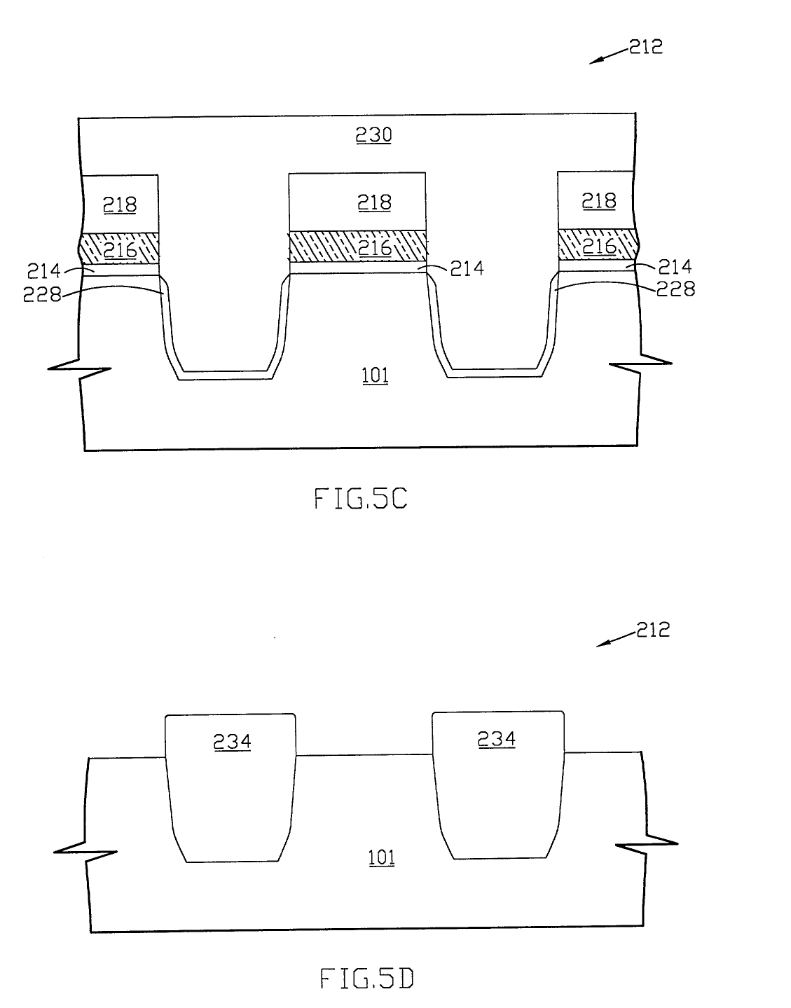

Referring to FIGS. 4A and 5A a cross-sectional view taken along cutting line 4-4 and 5-5 in FIG. 3 in accordance with the present invention in the formation of isolations in the memory device 100 is shown. It is noted that the formation of isolations in general is first formed in the process of producing a memory device. The method comprises the step of providing a semiconductor substrate 101 having two regions, 210 and 212, such as a silicon substrate having a common source region 210 and a first region 212 other than the common source region 210. The common source region 210 in FIG. 4A is the region where the common source line 126 is later formed in FIG. 3. The first region 212 is either in the core area or the peripheral area, as shown in FIG. 5A, which is in the core area. Then, a pad oxide layer 214 is formed on the silicon substrate 101 in a conventional manner, such as by thermal oxidation or chemical vapor deposition. It is noted that the term “oxide layer” described here comprises a silicon oxide layer but is not limited. An etching barrier layer 216 such as silicon nitride layer is subsequently formed on the pad oxide layer 214. Next, a cap oxide layer 218 is formed on the silicon nitride layer 216. The etching selectivity between silicon nitride layer and silicon oxide layer is the major reason for using these two materials in the embodiment, but any material with high selectivity within the etching process can be applied. In contrast to the conventional STI process, the cap oxide layer 218 on the silicon nitride layer 216 acts as a hard mask in a second STI etching process. Then, a first patterned photoresist 220 is formed on the cap oxide layer, wherein the first patterned photoresist defines a first opening 222 in the common source region and a second opening 224 in the first region.

Then, a first etching step is performed to accomplish very shallow and edge-tapered trenches in the silicon substrate 101 by using the first patterned photoresist 220 as a mask. That is to say, the dielectric stack including the cap oxide layer 218, the nitride layer 216, and the pad oxide layer 214 and a portion of the silicon substrate 101 are sequentially etched to form the first opening 222 and the second opening 224 till reaching a first depth in the silicon 101 substrate. The target of the first depth in the first etch step depends on the STI step height and process included field oxide loss which is about between 0 to 100 nm. Therefore, the etching depth is controlled such that the remained STI step height along the common source line is more than 50 nm before a floating gate polysilicon deposition. Subsequently to the first etch step, the first patterned photoresist 220 is removed by, for example, a stripper. It can be seen in FIGS. 4A and 5A, the first opening and the second opening is similar after the first etch step is performed.

Referring to FIGS. 4B and 5B, a second patterned photoresist 226 acts as a common source diffusion (CSD) mask and is formed on the cap oxide layer 218 with opening features 222, 224. Wherein the CSD mask covers the first opening 222 in the common source region 210 and exposes the second opening 224 in the first region 212. A second etch step is performed to continuously remove a portion of the semiconductor substrate 101 in the second opening 224 until a second depth (or final etch depth) is achieved. The final depth is usually deeper than the first depth that is a depth suitable for the purpose of isolating individual devices. During the second etch step, there can be a loss of the second patterned photoresist, and in the etching process of silicon material, a potion of silicon nitride can also be removed. Thus, a cap oxide layer is necessary to resist the etching attack for the protection of the first opening to maintain the first depth. Then, the second patterned photoresist 226 is removed. Therefore, the first opening 222 with the first depth and the second opening 224 with the final depth are formed in the common source region 210 and in the first region 212, respectively.

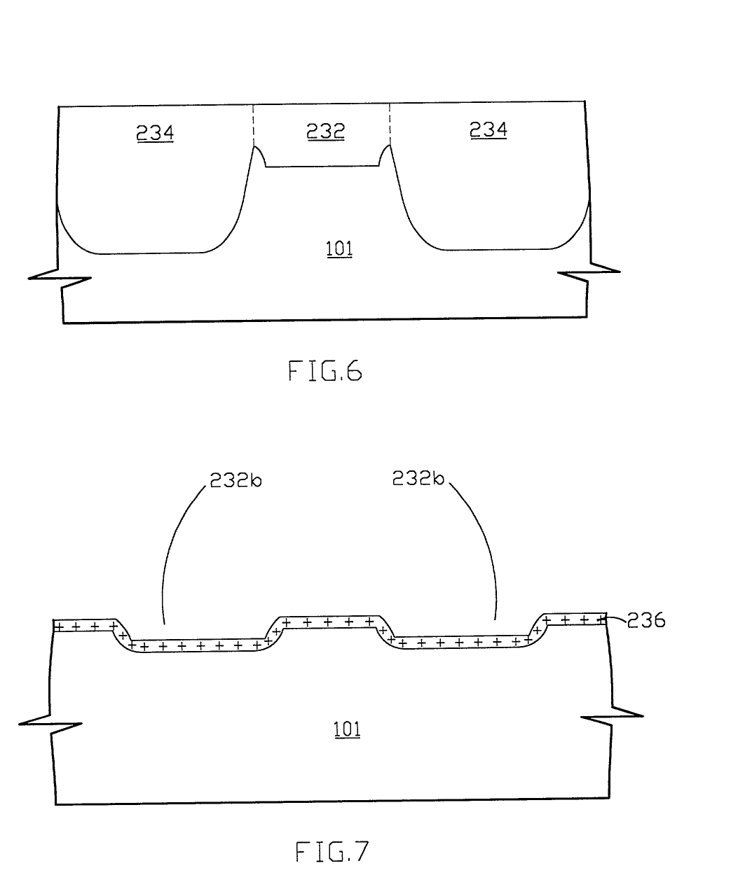

As illustrated in FIGS. 4C and 5C, a liner oxide layer 228 is formed in the first opening 222 and the second opening 224 by a thermal oxidation process. A fourth dielectric layer 230 is formed on the cap oxide layer 218, and the first opening 222 and the second opening 224 are filled with a dielectric material. For example, an oxide layer 230 is deposited on the cap oxide layer 218 and covers the first opening 222 and the second opening 224. The oxide layer 230 is then planarized to expose the silicon nitride layer 216 by chemical mechanical polishing (CMP) process. Next, the silicon nitride layer 216 and the pad oxide layer 214 are removed. Thus, a shallower isolation 232 is formed in the common source region 210, with a deeper depth trench isolation 234 in the first region 212 of the silicon substrate 101, as shown in FIGS. 4D and 5D. FIG. 6 is a cross-sectional view taken along cutting line 6-6 in FIG. 3. It is noted that the first isolation 232 is the field oxide 124b in FIG. 3, and the second isolation 234 is the field oxide 124a in FIG. 3. Additionally, in another embodiment, the present invention can also be applied while a first opening with a first depth in the common source region and a second opening with a second depth in the first region are individually formed in two pattern transferring processes. Thus, the purpose of creating shallower isolations in the common source region and enhanced isolations in other regions is achieved.

In the formation of a memory device with isolations in accordance with the present invention, a design rule is required for drain side cell gate edge to CSD (or common source region) edge. This rule assures the bit line to bit line isolation being constructed with STI of deeper depth. Another design rule of overlap for cell gate with CSD is optional. These rules are limited to the alignment accuracy between CSD and cell gate. A flash memory device with a layout similar to FIG. 3 can be formed in accordance with the present invention. Due to the formation of shallower STI in the common source region, the aspect ratio between the active area and the recessed isolation area is reduced. Thus, a common source line 236 after the implantation process is shown in FIG. 7, and the electrical continuity of the self-aligned source module with STI process, and more in general with completely recessed isolations of the semiconductor substrate, is greatly improved.

Although specific embodiments have been illustrated and described, it will be obvious to those skilled in the art that various modifications may be made without departing from what is intended to be limited solely by the appended claims.

What is claimed is:

1. A method for forming isolations in memory devices, said method comprising:
providing a semiconductor substrate having a common source region and a first region;
forming a first opening with a first depth in said common source region in said semiconductor substrate;
forming a second opening with a second depth in said first region in said semiconductor substrate, wherein said second depth is greater than said first depth; and
filling said first opening and said second opening with a dielectric material to form a first isolation in said common source region and a second isolation in said first region in said semiconductor substrate.

2. The method according to claim 1, wherein said semiconductor substrate is a silicon substrate.

3. The method according to claim 1, wherein said step of forming said first opening comprises:
forming a first dielectric layer on said semiconductor substrate;
forming a second dielectric layer on said first dielectric layer, wherein said second dielectric layer has a different etching selectivity from said first dielectric layer;
forming a third dielectric layer on said second dielectric layer, wherein said third dielectric layer has a different etching selectivity from said second dielectric layer;
forming a first patterned photoresist on said third dielectric layer, wherein said first patterned photoresist defines said first opening in said common source region;
etching said third dielectric layer, said second dielectric layer, said first dielectric layer, and a portion of said semiconductor substrate to form said first opening with a first depth in said common source region in said semiconductor substrate by using said first patterned photoresist as a mask; and
removing said first patterned photoresist.

4. The method according to claim 3, wherein said step of forming said second opening comprises:
forming a second patterned photoresist on said third dielectric layer, wherein said second patterned photoresist defines said second opening in said first region;
etching said third dielectric layer, said second dielectric layer, said first dielectric layer, and a portion of said semiconductor substrate to form said second opening with a second depth in said first region in said semiconductor substrate by using said second patterned photoresist as a mask, wherein said second depth is greater than said first depth; and
removing said second patterned photoresist.

5. The method according to claim 3, wherein said first dielectric layer is a pad oxide layer.

6. The method according to claim 5, wherein said second dielectric layer is a silicon nitride layer.

7. The method according to claim 6, wherein said third dielectric layer is a cap oxide layer.

8. The method according to claim 3, wherein said step of forming said first isolation and said second isolation comprises:
forming a fourth dielectric layer in said first opening and said second opening;
forming a fifth dielectric layer on said third dielectric layer and filling said first opening and said second opening with said dielectric material;
planarizing said fifth layer to expose said second dielectric layer; and
removing said second dielectric layer and said first dielectric layer.

9. The method according to claim 1, further comprising forming a gate structure, a source region, a drain region, and a common source line to form a flash memory device.

10. A method for forming isolations in memory devices, said method comprising:
providing a silicon substrate having a common source region and a first region;
forming a pad oxide layer on said silicon substrate;
forming a silicon nitride layer on said pad oxide layer;
forming a cap oxide layer on said silicon nitride layer;
forming a first opening with a first depth in said common source region in said silicon substrate;
forming a second opening with a second depth in said first region in said silicon substrate, wherein said second depth is greater than said first depth; and
filling said first opening and said second opening with a dielectric material to form a first isolation in said common source region and a second isolation in said first region in said silicon substrate.

11. The method according to claim 10, wherein said step of forming said first opening comprises:
forming a first patterned photoresist on said cap oxide layer, wherein said first patterned photoresist defines said first opening in said common source region;
etching said cap oxide layer, said silicon nitride layer, said pad oxide layer, and a portion of said silicon substrate to form said first opening with a first depth in said common source region in said silicon substrate by using said first patterned photoresist as a mask; and
removing said first patterned photoresist.

12. The method according to claim 10, wherein said step of forming said second opening with said second depth comprises:
forming a second patterned photoresist on said cap oxide layer, wherein said second patterned photoresist defines said second opening in said first region;
etching said cap oxide layer, said silicon nitride layer, said pad oxide layer, and a portion of said silicon substrate to form said second opening with a second depth in said first region in said silicon substrate by using said second patterned photoresist as a mask, wherein said second depth is greater than said first depth; and
removing said second patterned photoresist.

13. The method according to claim 10, wherein said step of forming said first isolation and said second isolation comprises:
forming a liner oxide layer in said first opening and said second opening;
forming a dielectric layer on said cap oxide layer and filling said first opening and said second opening with said dielectric material;
planarizing said dielectric layer to expose said silicon nitride layer; and
removing said silicon nitride layer, and said pad oxide layer.

14. The method according to claim 10, further comprising forming a gate structure, a source region, a drain region, and a common source line to form a flash memory device.

15. A method for forming isolations in a semiconductor substrate having a common source region and a first region, said method comprises:
forming a pad oxide layer on said semiconductor substrate;
forming a silicon nitride layer on said pad oxide layer;
forming a cap oxide layer on said silicon nitride layer;
forming a first patterned photoresist on said cap oxide layer, wherein said first patterned photoresist defines a first opening in said common source region and a second opening in said first region;
etching said cap oxide layer, said silicon nitride layer, said pad oxide layer, and a portion of said semiconductor substrate to form said first opening with a first depth in said common source region of said semiconductor substrate and said second opening in said first region of said semiconductor substrate by using said first patterned photoresist as a mask;
removing said first patterned photoresist;
forming a second patterned photoresist on said cap oxide layer, wherein said second patterned photoresist covers said first opening and exposes said semiconductor substrate in said second opening;
removing said semiconductor substrate in said second opening till a second depth is reached, wherein said second depth is greater than said first depth by using said second patterned photoresist as a mask;
removing said patterned photoresist;
forming a liner oxide layer in said first opening and said second opening;
forming a dielectric layer on said cap oxide layer and filling said first opening and said second opening with a dielectric material;
planarizing said dielectric layer to expose said silicon nitride layer; and
removing said silicon nitride layer and said pad oxide layer.

16. The method according to claim 15, wherein said semiconductor substrate is a silicon substrate.

17. The method according to claim 15, further comprising forming a gate structure, a source region, a drain region, and a common source line to form a flash memory device.
